(19) United States
(12) Patent Application Publication
(10) Pub. No.: US 2009/0140807 A1
(43) Pub. Date: Jun. 4, 2009

(54) DIFFERENTIAL AMPLIFIER CIRCUIT

(75) Inventors: Jun Takasoh, Tokyo (JP); Norio Higashisaka, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/046,558

(22) Filed: Mar. 12, 2008

(30) Foreign Application Priority Data
Nov. 30, 2007 (JP) 2007-310659

(51) Int. Cl. H03F 3/45

(52) U.S. Cl. 330/252

(57) ABSTRACT

A differential amplifier circuit has first and second transistors composing a differential pair; a first inductor connected between the output terminal of the first transistor and a power source; a second inductor connected between the output terminal of the second transistor and the power source; a first transmission gate connected in series with the first inductor; and a second transmission gate connected in series with the second inductor.

### BACKGROUND OF THE INVENTION

1. Field of the Invention

The present invention relates to a differential amplifier circuit that can externally and easily controls inductance.

2. Background Art

In a differential amplifier circuit, inductance has much effect on operation bands. Therefore, to widen the operation bands, inductor peaking is used. By inductor peaking, peak gain is generated in a high-frequency region, resulting in band widening.

Inductance also has much effect on the output eye pattern of the differential amplifier circuit. If inductance is larger than a predetermined value, there is possibility that the overshoot or undershoot of the eye pattern occurs, causing increase in jittering. On the other hand, if inductance is smaller than a predetermined value, the shortage of the bands on the differential amplifier circuit is caused, and in the eye pattern, the shortage of Tr/Tf or the like is caused. Therefore, in a high-frequency amplifier of a 10 Gbps class, the optimization of inductance is important.

Here, the effect of inductor peaking will be described. FIG. 22 is a graph showing the frequency characteristics of an ordinary differential amplifier circuit. When the resistance component of the differential amplifier is only a load resistance, the gain S21 of the differential amplifier is as shown by the solid line. Specifically, in a low-frequency region, S21 is determined by the load resistance, and in a high-frequency region, S21 is deteriorated due to band deterioration.

To compensate the deterioration in the high-frequency region, the peaking effect of an inductor is used. When the resistance components of the differential amplifier circuit are a load resistance and an inductor, S21 becomes as shown by the broken line, and frequency characteristics in the high-frequency region are improved.

When the resistance component is only a load resistance, S21 equals to R. On the other hand, when the resistance components are a load resistance and an inductor, S21 becomes R+jωL. Here, R is a real resistance component, j is an imaginary number, ω is the angle frequency of transmitted waves, and L represents inductance. By thus installing an inductor, frequency characteristics in the high-frequency region can be improved.

In Japanese Patent Laid-Open No. 2000-138415, although it is described that the semiconductor laser circuit is formed so that the peaking characteristics are controllable, the specific configuration is not described. In Japanese Patent Laid-Open No. 10-163856, although it is described that gain is controlled by controlling load resistance values, it is not described about controlling peak gain or peak frequency.

### SUMMARY OF THE INVENTION

In the simulation model of inductance, highly accurate layout extraction is performed by electromagnetic field analysis and the like. However, in 10-Gbps-class high frequency, the actually measured value of inductance is difficult to agree with the result of simulation. Therefore, inductance must be agreed by actual measurement.

In addition, even in the same circuit, optical inductance differs depending on the using environment, the system, the application, ambient temperature, operation frequency, power source voltage, input waveform and desired output waveform, and the finished state of the transmission path of inputs and outputs. However, since conventional differential amplifier circuits could not externally and easily control inductance, trial productions or dummy productions (producing a plurality of circuits for the same purpose) for adjustment had to carry out many times.

To solve such problems, it is an object of the present invention to provide a differential amplifier circuit that can externally and easily control inductance.

According to one aspect of the present invention, a differential amplifier circuit comprises first and second transistors composing a differential pair; a first inductor connected between the output terminal of said first transistor and a power source; a second inductor connected between the output terminal of said second transistor and said power source; a first transmission gate connected in series with said first inductor; and a second transmission gate connected in series with said second inductor.

According to the present invention, inductance can be externally and easily controlled.

Other and further objects, features and advantages of the invention will appear more fully from the following description.

### BRIEF DESCRIPTION OF THE DRAWINGS

FIG. 1 is a circuit diagram showing a differential amplifier circuit according to the first embodiment of the present invention.

FIG. 2 is a graph showing the frequency characteristics of the differential amplifier circuit shown in FIG. 1.

FIG. 3 is a circuit diagram showing a differential amplifier circuit according to the second embodiment of the present invention.

FIG. 4 is a graph showing the frequency characteristics of the differential amplifier circuit shown in FIG. 3.

FIG. 5 is a circuit diagram showing a differential amplifier circuit according to the third embodiment of the present invention.

FIG. 6 is a graph showing the frequency characteristics of the differential amplifier circuit shown in FIG. 5.

FIG. 7 is a circuit diagram showing a differential amplifier circuit according to the fourth embodiment of the present invention.

FIG. 8 is a circuit diagram showing a differential amplifier circuit according to the fifth embodiment of the present invention.

FIG. 9 is a circuit diagram showing a differential amplifier circuit according to the sixth embodiment of the present invention.

FIG. 10 is a graph showing the inductance characteristics of the circuit shown in FIG. 9.

FIG. 11 is a circuit diagram showing a differential amplifier circuit according to the seventh embodiment of the present invention.

FIG. 12 is a graph showing the inductance characteristics of the circuit shown in FIG. 11.

FIG. 13 is a graph showing inductance characteristics when the gate lengths and gate widths of the plurality of transmission gates are different from each other in the circuit of FIG. 11.

FIG. 14 is a circuit diagram showing a differential amplifier circuit according to the eighth embodiment of the present invention.

FIG. 15 is a circuit diagram showing a differential amplifier circuit according to the ninth embodiment of the present invention.

FIG. 16 is a graph showing the inductance characteristics of the circuit shown in FIG. 15.

FIG. 17 is a circuit diagram showing a differential amplifier circuit according to the tenth embodiment of the present invention.

FIG. 18 are graphs showing the characteristics when the circuit shown in FIG. 3 is analogically controlled.

FIG. 19 are graphs showing the characteristics when the circuit shown in FIG. 3 is digitally controlled.

FIG. 20 are graphs showing the characteristics when the circuit shown in FIG. 1 is analogically controlled.

FIG. 21 are graphs showing the characteristics when the circuit shown in FIG. 1 is digitally controlled.

FIG. 22 is a graph showing the frequency characteristics of an ordinary differential amplifier circuit.

### DETAILED DESCRIPTION OF THE PREFERRED EMBODIMENTS

### First Embodiment

FIG. 1 is a circuit diagram showing a differential amplifier circuit according to the first embodiment of the present invention. The transistor 10 (first transistor) and the transistor 11 (second transistor) are current switch transistors that form a differential pair. The transistors 10 and 11 may be bipolar transistors or may be CMOS transistors. Differential inputs IN_P and IN_N are inputted into the gates of the transistors 10 and 11, respectively; and differential outputs OUT_P and OUT_N are outputted from the drains (output terminals) of the transistors 10 and 11, respectively.

The sources of the transistors 10 and 11 are connected in common, and a constant current source 12 is connected between the sources and the grounding point. A load resistance 13 (first load resistance) and an inductor 14 (first inductor) are serially connected between the drain of the transistor 10 and the power source. A load resistance 15 (second load resistance) and an inductor 16 (second inductor) are serially connected between the drain of the transistor 11 and the power source.

In the present embodiment, transmission gates 17 and 18 (first and second transmission gates, respectively) for adjusting inductance are added to an ordinary differential amplifier circuit using inductor peaking as described above. The transmission gate 17 is serially connected to the inductor 14, and the transmission gate 18 is serially connected to the inductor 16. The transmission gates 17 and 18 are composed of an NMOS transistor and a PMOS transistor. Complementary signals are inputted into the gate of the PMOS transistor and the gate of the NMOS transistor.

The operation of the above-described differential amplifier circuit will be described. The gate voltage of the transmission gates 17 and 18 serially connected to the inductors 14 and 16, respectively, for improving the operation band are adjusted. Specifically, the gate voltage of the NMOS transistor and the PMOS transistor composing the transmission gates 17 and 18, respectively, is adjusted. Thereby, the impedance of the transmission gates 17 and 18 (impedance between the inductors 14, 16, and the load resistances 13, 15) is varied to vary the inductance of the differential amplifier circuit.

Here, when the impedance of the transmission gates 17 and 18 is expressed by R_{TG}, the gain S21 of the differential amplifier circuit is R+jωL+R_{TG}. If R or R_{TG} is large, the Q value (quality factor) of the inductors is deteriorated, and the L component tends to look smaller. In the present embodiment, therefore, the variable real resistance component R_{TG} is raised or lowered to vary the inductance of the differential amplifier circuit, and to adjust the peaking quantity (broken line in FIG. 22).

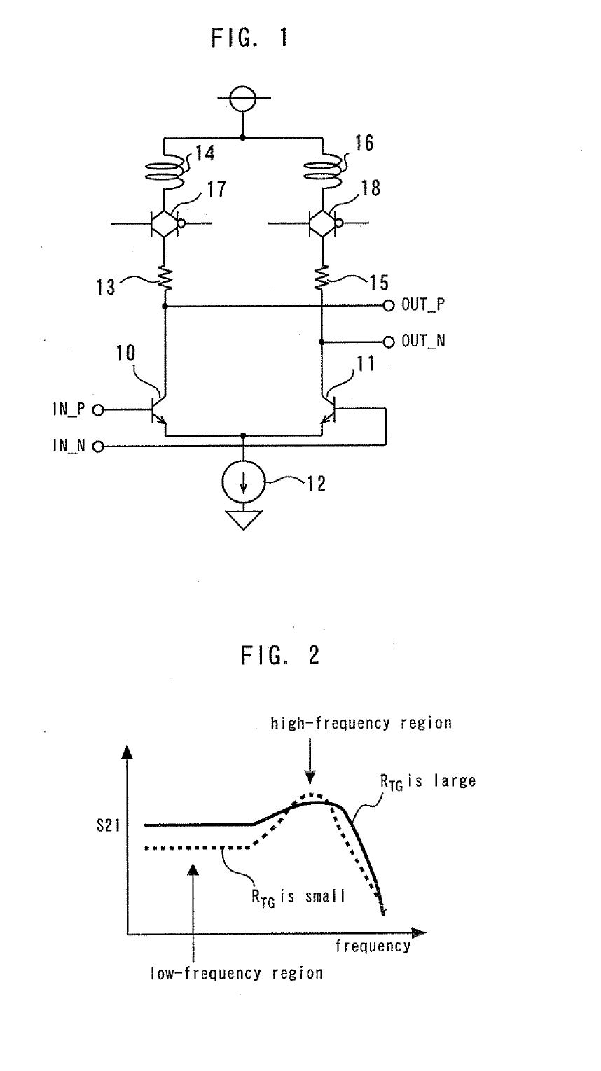

FIG. 2 is a graph showing the frequency characteristics of the differential amplifier circuit shown in FIG. 1. The solid line indicates the case wherein the impedance R_{TG} of the transmission gates 17 and 18 is large, and the broken line indicates the case wherein the R_{TG} is small.

If R_{TG} is large, the inductance L (peak value) is small. In this case, S21 is R+jωL(small)+R_{TG}(large). Therefore, since jωL is small, S21 is small in the high-frequency region. However, jωL looks to be 0Ω in the low-frequency region, and since S21 is R+R_{TG} (large), S21 is large.

On the other hand, if R_{TG} is small, inductance L is large. In this case, S21 is R+jωL(large)+R_{TG}(small). Therefore, since jωL is large, S21 is large in the high-frequency region. However, jωL looks to be 0Ω in the low-frequency region, and since S21 is R+R_{TG} (small), S21 is deteriorated compared with the case wherein R_{TG} is large.

As described above, in the differential amplifier circuit according to the present invention, inductance can be easily controlled from the exterior only by controlling the gate voltage of the transmission gates 17 and 18. Therefore the number of trial productions or dummy productions for optimizing inductance can be reduced. In addition, since the fine control of inductance becomes possible, the matching accuracy of optimum values is elevated.

### Second Embodiment

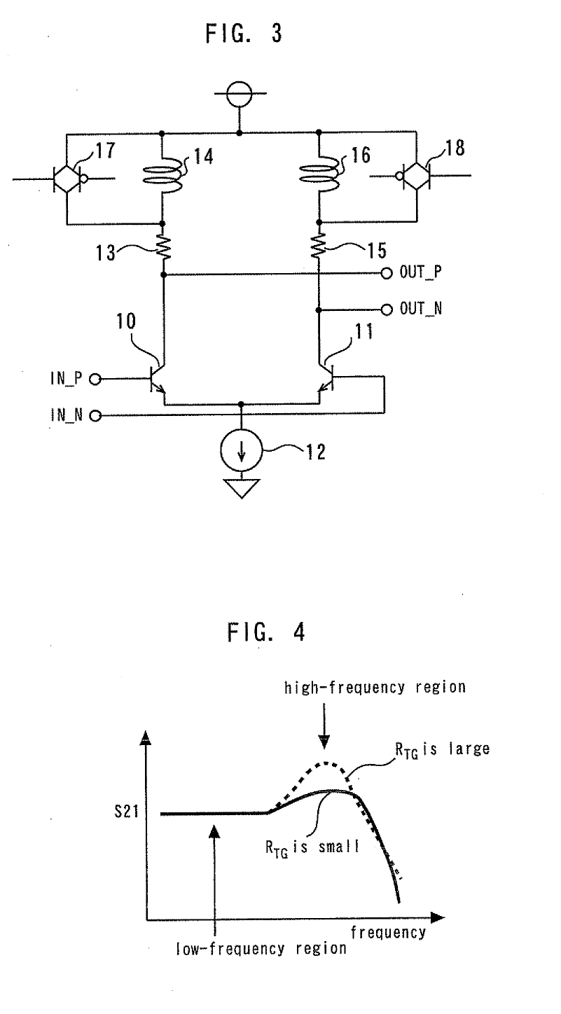

FIG. 3 is a circuit diagram showing a differential amplifier circuit according to the second embodiment of the present invention. The transmission gate 17 is connected in parallel to the inductor 14, and the transmission gate 18 is connected in parallel to the inductor 16. Other configurations are identical to the configurations of the first embodiment.

The operation of the differential amplifier circuit according to the second embodiment will be described. By varying the gate voltage of the transmission gates 17 and 18 in the same manner as in the first embodiment, the impedances of the transmission gates 17 and 18 are controlled to control inductance. Thereby, the effect equivalent to the effect of the first embodiment can be obtained. However, the relationship between the impedances of the transmission gates 17, 18 and the inductance of the differential amplifier circuit is different from the relationship in the first embodiment. This will be described below.

FIG. 4 is a graph showing the frequency characteristics of the differential amplifier circuit shown in FIG. 3. Since the inductance L is raised by raising the impedance R_{TG} of the transmission gates 17 and 18, S21 becomes R+jωL (large). On the other hand, since the inductance L is lowered when R_{TG} is lowered, S21 becomes R+jωL (small). In the high-frequency region, therefore, since S21 is larger as R_{TG} is larger, the relationship between R_{TG} and the inductance L is reversed from the relationship in the first embodiment. In the low-frequency region, since jωL looks to be 0Ω and S21 becomes R, S21 becomes substantially constant regardless of R_{TG}.

### Third Embodiment

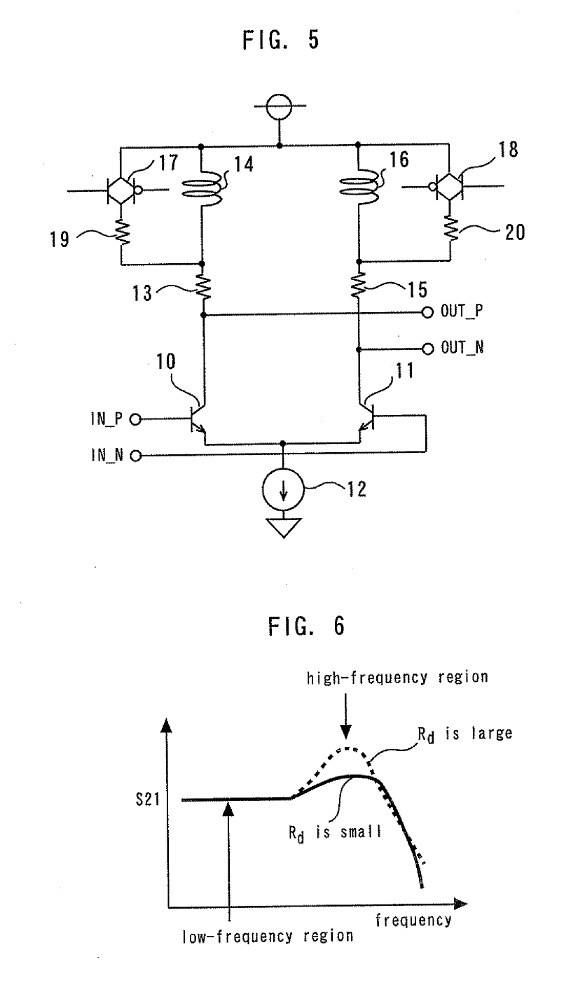

FIG. 5 is a circuit diagram showing a differential amplifier circuit according to the third embodiment of the present invention. In this circuit, resistors 19 and 20 (first and second resistors) are inserted to the circuit of the second embodiment as dumping resistors. The resistor 19 is connected to the inductor 14 in parallel and connected to the transmission gate 17 in series. The resistor 20 is connected to the inductor 16 in parallel and connected to the transmission gate 18 in series.

FIG. 6 is a graph showing the frequency characteristics of the differential amplifier circuit shown in FIG. 5. The solid line indicates the case wherein the impedance R_{d} of the resistors 19 and 20 is small, and the broken line indicates the case wherein the R_{d} is large. Here, it is assumed that the impedance R_{TG} of the transmission gates 17 and 18 is not varied.

Since the inductance L is raised by raising the impedance R_{d} of the resistors 19 and 20, S21 becomes R+jωL (large). On the other hand, since the inductance L is lowered when R_{d} is lowered, S21 becomes R+jωL(small). In the high-frequency region, therefore, S21 is larger as R_{d} of the resistors 19 and 20 is larger. In the low-frequency region, since jωL looks to be 0Ω and S21 becomes R, S21 becomes substantially constant regardless of R_{d}. As described above, by inserting the resistors 19 and 20, the inductor component is not varied in the low-frequency region, but can be varied only in the high-frequency region.

### Fourth Embodiment

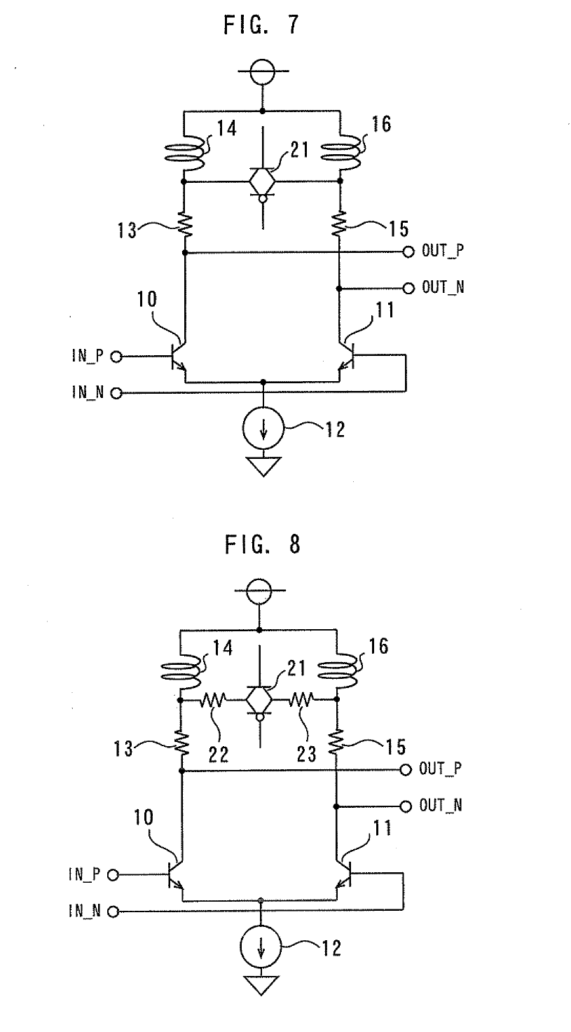

FIG. 7 is a circuit diagram showing a differential amplifier circuit according to the fourth embodiment of the present invention. A transmission gate 21 is connected between the inductor 14 and the inductor 16 in place of the transmission gates 17 and 18. Specifically, a transmission gate 21 is cross-connected to the differential pair of the differential amplifier circuit. Other configurations are identical to the configurations of the first embodiment.

The characteristics of the differential amplifier circuit according to the fourth embodiment are identical to the characteristics of the second embodiment (FIG. 4). Specifically, in the high-frequency region, S21 is larger as the impedance R_{TG} of the transmission gate 21 is larger; and in the low-frequency region, S21 becomes substantially constant regardless of R_{TG}.

### Fifth Embodiment

FIG. 8 is a circuit diagram showing a differential amplifier circuit according to the fifth embodiment of the present invention. In this circuit, resistors 22 and 23 are inserted to the circuit of the fourth embodiment as dumping resistors. The resistors 22 and 23 are connected to the transmission gate 21 in series.

The characteristics of the differential amplifier circuit according to the fifth embodiment are identical to the characteristics of the third embodiment (FIG. 6). Specifically, by inserting the resistors 19 and 20, the inductor component is not varied in the low-frequency region, but can be varied only in the high-frequency region.

### Sixth Embodiment

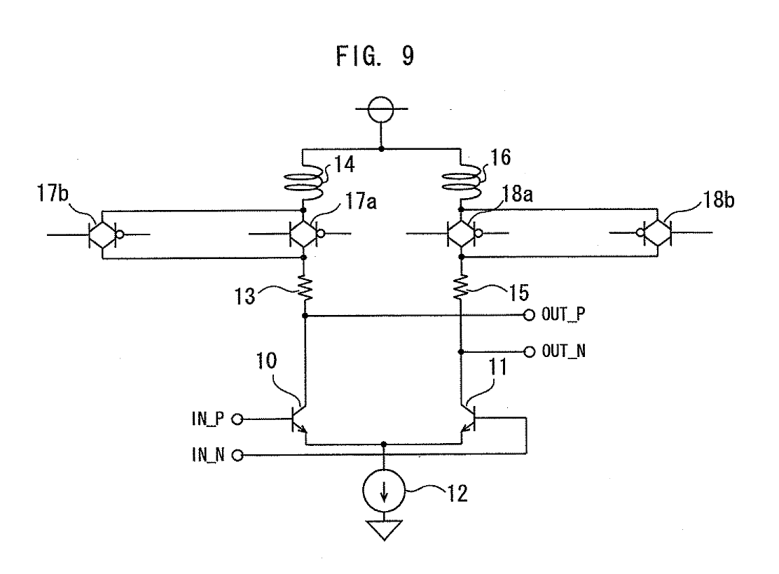

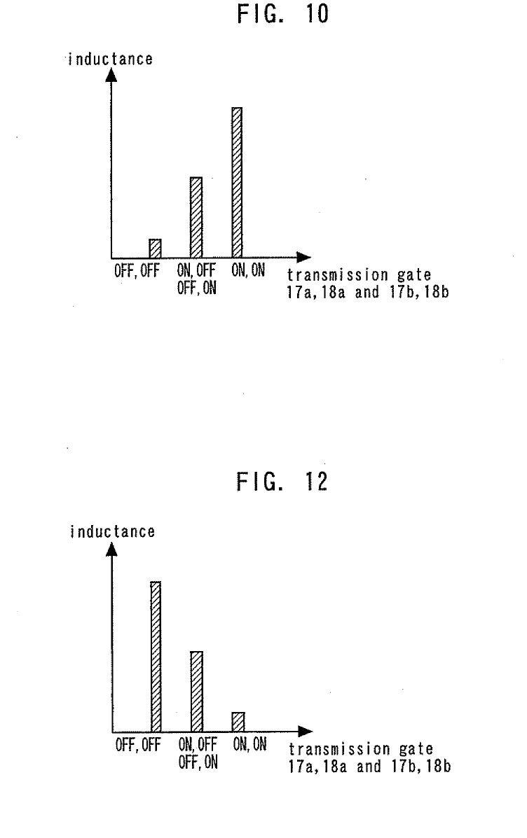

FIG. 9 is a circuit diagram showing a differential amplifier circuit according to the sixth embodiment of the present invention. The differential amplifier circuit has a plurality of transmission gates 17a and 17b connected in parallel as a first transmission gate connected in series to an inductor 14. The differential amplifier circuit has also a plurality of transmission gates 18a and 18b connected in parallel as a second transmission gate connected in series to an inductor 16. Other configurations are identical to the configurations of the first embodiment.

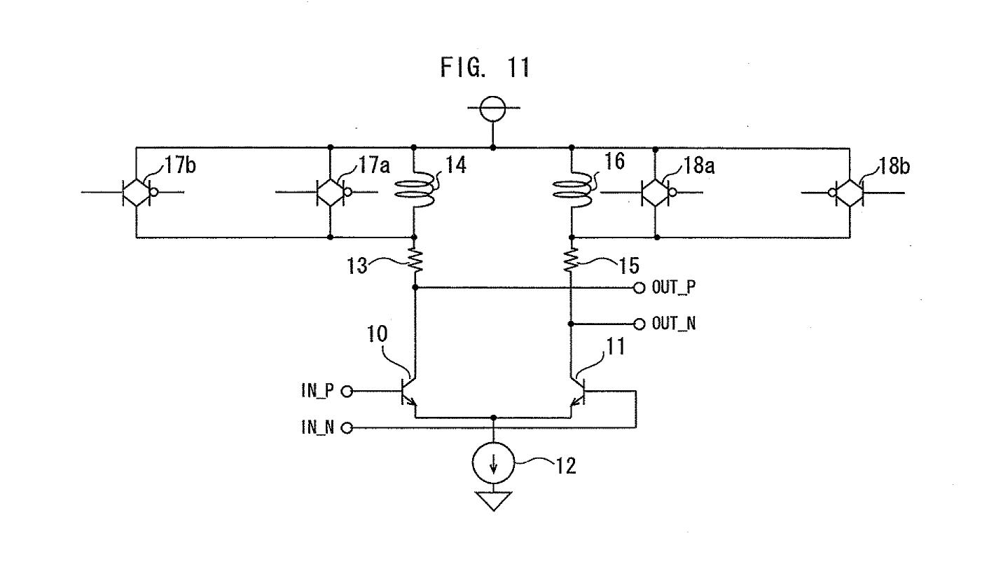

FIG. 10 is a graph showing the inductance characteristics of the circuit shown in FIG. 9. When all the transmission gates 17a, 18a, 17b and 18b are turned on, the impedance of the entire transmission gates becomes the minimum, and the inductance of the differential amplifier circuit becomes the maximum. However, even if all the transmission gates 17a, 18a, 17b and 18b are turned on, the real impedance does not become 0Ω. When all the transmission gates 17a, 18a, 17b and 18b are turned off, the impedance of the entire transmission gates becomes the maximum, and the inductance of the differential amplifier circuit becomes the minimum. When the transmission gates 17a and 18a are turned on and the transmission gates 17b and 18b are turned off, and vice versa, the impedance of the entire transmission gates becomes intermediate, and the inductance of the differential amplifier circuit also becomes intermediate. Therefore, the adjusting bit of the inductance of the differential amplifier circuit becomes 2 bits (3 stages).

As described above, by using a plurality of transmission gates connected in parallel as the first and second transmission gates, the adjusting bit of the inductance of the differential amplifier circuit can be increased, and the control range can be made fine.

### Seventh Embodiment

FIG. 11 is a circuit diagram showing a differential amplifier circuit according to the seventh embodiment of the present invention. The differential amplifier circuit has a plurality of transmission gates 17a and 17b connected in parallel as a first transmission gate connected in parallel to an inductor 14. The differential amplifier circuit has also a plurality of transmission gates 18a and 18b connected in parallel as a second transmission gate connected in parallel to an inductor 16. Other configurations are identical to the configurations of the second embodiment.

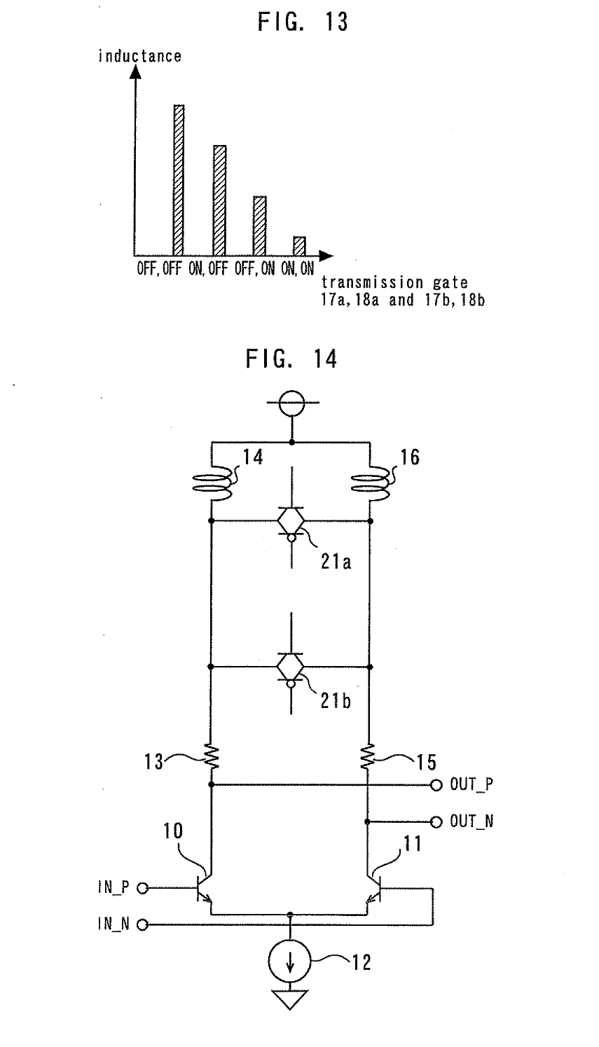

FIG. 12 is a graph showing the inductance characteristics of the circuit shown in FIG. 11. The inductance characteristics are the characteristics wherein the inductance characteristics of the circuit shown in FIG. 9 (FIG. 10) are reversed. By thus using a plurality of transmission gates connected in parallel as the first and second transmission gates, the adjusting bit of the inductance of the differential amplifier circuit can be increased, and the control range can be made fine.

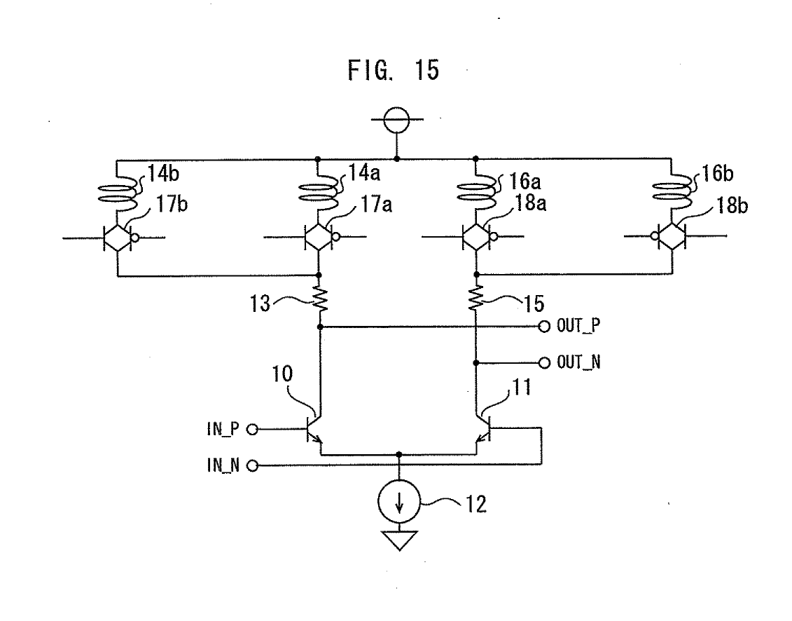

It is preferable that the gate lengths and gate widths of the plurality of transmission gates 17a, 17b and 18a, 18b are different from each other. Thereby, the impedance when the transmission gates 17a, 17b and 18a, 18b are turned on or turned off can be varied. FIG. 13 is a graph showing inductance characteristics when the gate lengths and gate widths of the plurality of transmission gates are different from each other in the circuit of FIG. 11. As shown in the graph, the inductance of the differential amplifier circuit can be adjusted in four steps. Therefore, the adjusting bit of the inductance of the differential amplifier circuit can further be increased, and the control range can further be made fine.

### Eighth Embodiment

FIG. 14 is a circuit diagram showing a differential amplifier circuit according to the eighth embodiment of the present invention. The differential amplifier circuit has a plurality of transmission gates 21a and 21b connected in parallel as a transmission gate cross-connected to the differential pair of the differential amplifier circuit. Other configurations are identical to the configurations of the fourth embodiment.

The characteristics of the differential amplifier circuit according to the eighth embodiment are equivalent to the characteristics of the seventh embodiment (FIG. 12). By thus using a plurality of transmission gates connected in parallel as the transmission gate, the adjusting bit of the inductance of the differential amplifier circuit can be increased, and the control range can be made fine.

### Ninth Embodiment

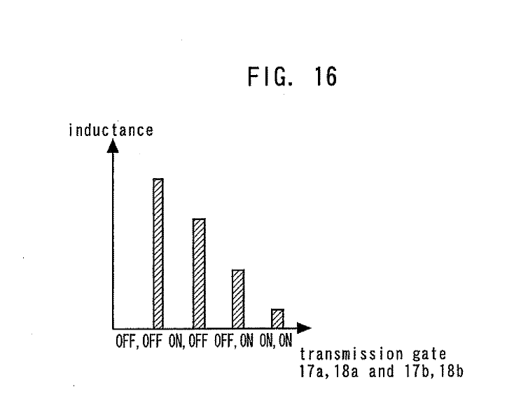

FIG. 15 is a circuit diagram showing a differential amplifier circuit according to the ninth embodiment of the present invention. In addition to the circuit of the first embodiment, the differential amplifier circuit has a plurality of inductors 14a and 14b connected in parallel as a first inductor. The differential amplifier circuit has a plurality of inductors 16a and 16b connected in parallel as a second inductor. Transmission gates 17a, 17b, 18a and 18b are connected in series to the inductors 14a, 14b, 16a and 16b, respectively. To widen the adjusting ranges the inductors 14a, 14b, and 16a, 16b are laid out so as to have different inductances.

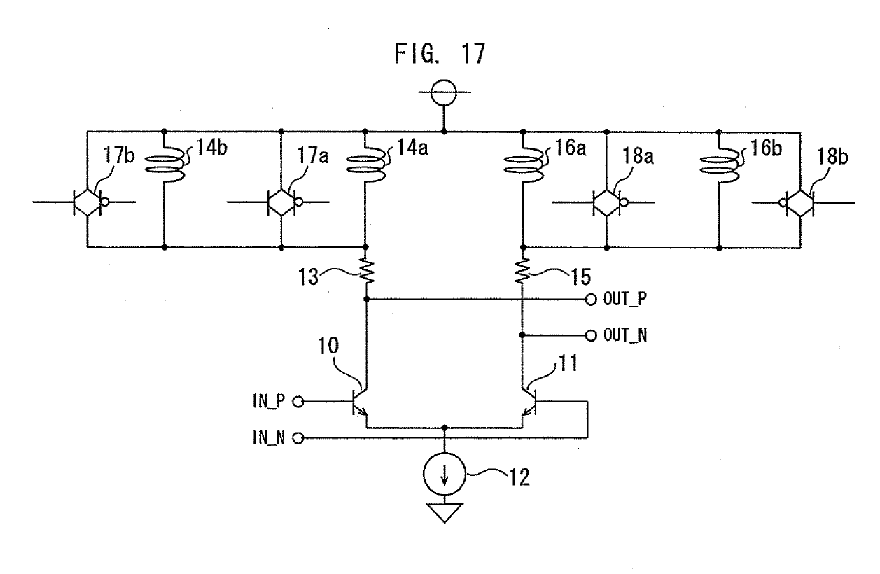

FIG. 16 is a graph showing the inductance characteristics of the circuit shown in FIG. 15. As shown in the drawing, the inductance of the differential amplifier circuit can be adjusted in four steps. Therefore, the adjusting bit of the inductance of the differential amplifier circuit can further be increased, and the control range can further be made fine.

### Tenth Embodiment

FIG. 17 is a circuit diagram showing a differential amplifier circuit according to the tenth embodiment of the present invention. In addition to the circuit of the second embodiment, the differential amplifier circuit has a plurality of inductors 14a and 14b connected in parallel as a first inductor. The differential amplifier circuit has a plurality of inductors 16a and 16b connected in parallel as a second inductor. Transmission gates 17a, 17b, 18a and 18b are connected in parallel to the inductors 14a, 14b, 16a and 16b, respectively. To widen the adjusting range, the inductors 14a, 14b, and 16a, 16b are laid out so as to have different inductances.

The characteristics of the differential amplifier circuit according to the tenth embodiment are equivalent to the characteristics of the ninth embodiment (FIG. 16). Therefore, the adjusting bit of the inductance of the differential amplifier circuit can further be increased, and the control range can further be made fine.

In the differential amplifier circuit according to the above-described embodiments 1 to 10, the gate voltage of the transmission gate (NMOS transistor and PMOS transistor) is analogically or digitally controlled.

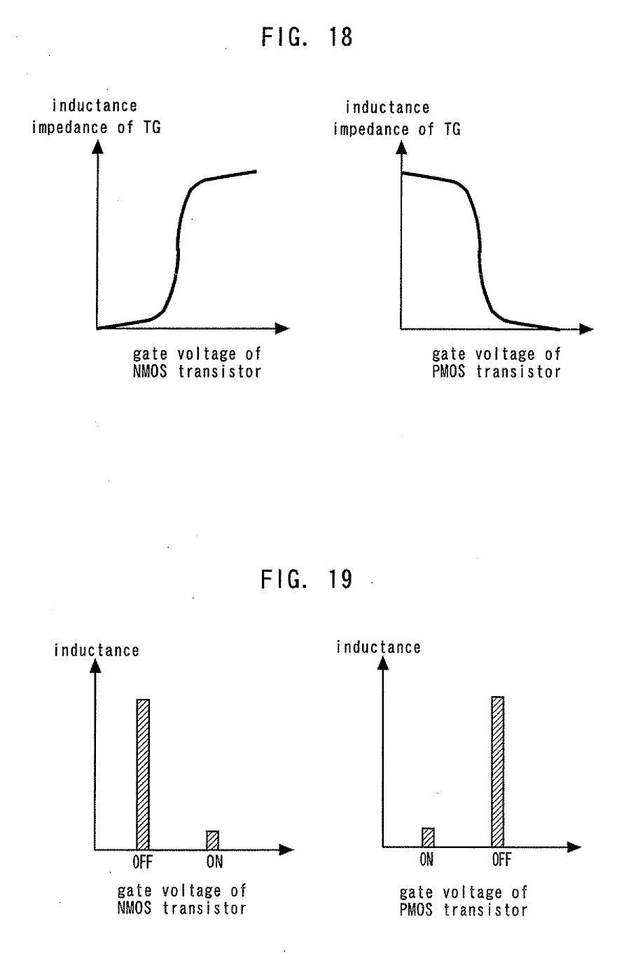

FIG. 18 are graphs showing the characteristics when the circuit shown in FIG. 3 is analogically controlled. When the gate voltage of the NMOS transistor is raised, the impedance of the transmission gate TG is lowered; therefore, the inductance of the differential amplifier circuit is lowered. On the other hand, when the gate voltage of the PMOS transistor is raised, the impedance of the transmission gate TG is raised; therefore, the inductance of the differential amplifier circuit is raised. By thus analogically controlling the gate voltage of the transmission gate, the optimum point of the inductance of the differential amplifier circuit can be adjusted. However, the region that is virtually adjusted is only a narrow region that is being rapidly varied.

FIG. 19 are graphs showing the characteristics when the circuit shown in FIG. 3 is digitally controlled. When the gate voltage of the NMOS transistor is raised to a High level to turn the NMOS transistor on, the impedance of the transmission gate is lowered; therefore, the inductance of the differential amplifier circuit is lowered. On the other hand, when the gate voltage of the PMOS transistor is lowered to a Low level to turn the PMOS transistor on, the impedance of the transmission gate is lowered; therefore, the inductance of the differential amplifier circuit is lowered. By thus digitally controlling the gate voltage of the transmission gate, the inductance of the differential amplifier circuit can be digitally adjusted. The characteristics of the circuit shown in FIG. 7 subjected to analog control or digital control are identical to the characteristics of the circuit shown in FIG. 3.

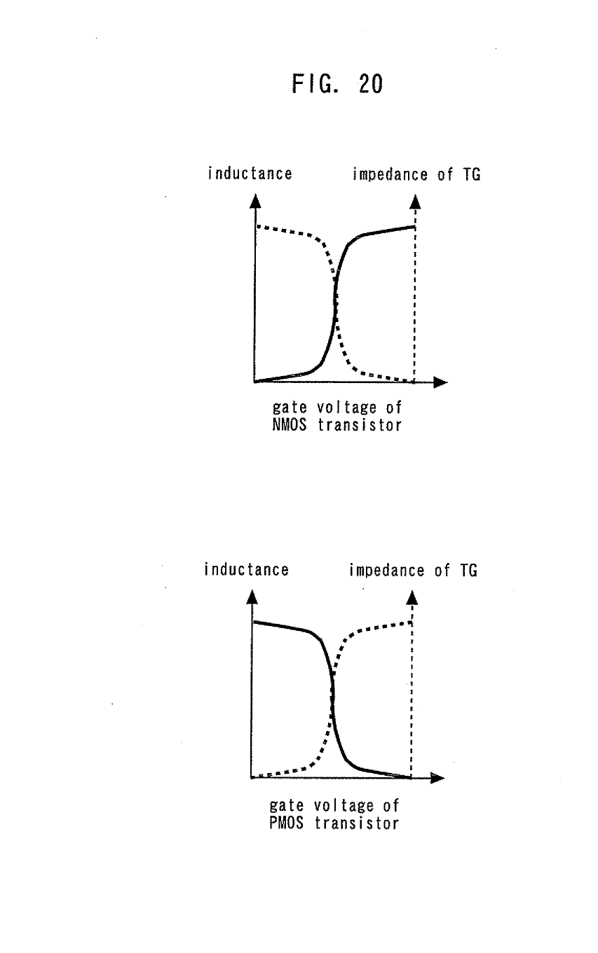

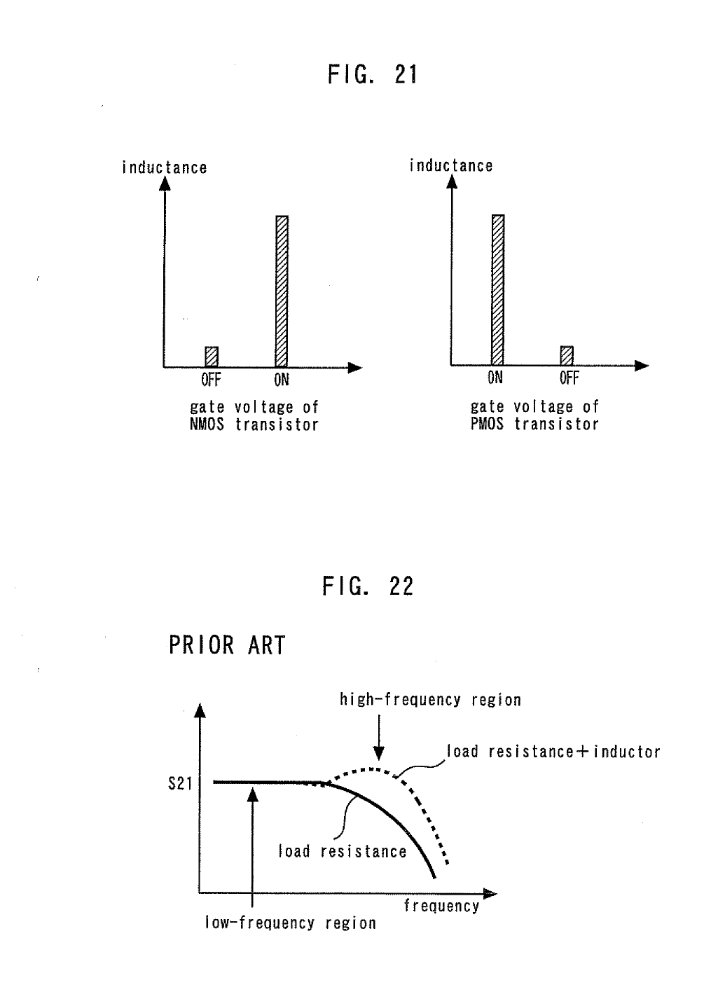

FIG. 20 are graphs showing the characteristics when the circuit shown in FIG. 1 is analogically controlled. FIG. 21 are graphs showing the characteristics when the circuit shown in FIG. 1 is digitally controlled. The characteristics of the circuit shown in FIG. 1 are reversed to the characteristics of the circuit shown in FIG. 3. This is because the characteristics of the circuit shown in FIG. 1 (FIG. 2) are reversed to the characteristics of the circuit shown in FIG. 3 (FIG. 4).

In the above-described embodiments, the transmission gate has a PMOS transistor and an NMOS transistor connected in parallel. However, the present invention is not limited thereto, but configurations wherein a transmission gate has one of a PMOS transistor and an NMOS transistor may also be used. Thereby, when the gate voltage of the transmission gate is analogically controlled, the characteristics are easily made to be linear, and the control range is somewhat widened.

Also in the above-described embodiments, an inductor layout is used as the configuration to generate inductor peaking. However, the present invention is not limited thereto, but the inductor component of a wire may be used as the inductor. Specifically, transistors 10, 11 and a transmission gate may be formed on an IC chip, and the inductor component of the wire connecting the IC chip to the power source terminal of the lead frame may be used as the inductor.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2007-310659, filed on Nov. 30, 2007 including specification, claims, drawings and summary, on which the Convention priority of the present application is based, are incorporated herein by reference in its entirety.

1. A differential amplifier circuit comprising:
first and second transistors composing a differential pair;
a first inductor connected between an output terminal of said first transistor and a power source;
a second inductor connected between an output terminal of said second transistor and said power source;
a first transmission gate connected in series with said first inductor; and
a second transmission gate connected in series with said second inductor.

2. A differential amplifier circuit comprising:
first and second transistors composing a differential pair;
a first inductor connected between an output terminal of said first transistor and a power source;
a second inductor connected between an output terminal of said second transistor and said power source;
a first transmission gate connected in parallel with said first inductor; and
a second transmission gate connected in parallel with said second inductor.

3. The differential amplifier circuit according to claim 2 further comprising:
a first resistor connected in parallel with said first inductor and connected in series with said first transmission gate, and a second resistor connected in parallel with said second inductor and connected in series with said second transmission gate.

4. A differential amplifier circuit comprising:
first and second transistors composing a differential pair;
a first inductor connected between an output terminal of said first transistor and a power source;
a second inductor connected between an output terminal of said second transistor and said power source; and
a transmission gate connected between said first inductor and said second inductor.

5. The differential amplifier circuit according to claim 4 further comprising a resistor connected between said first inductor and said second inductor, and connected in series with said transmission gate.

6. The differential amplifier circuit according to claim 1, wherein each of said first and second transmission gates comprises a plurality of transmission gates connected in parallel.

7. The differential amplifier circuit according to claim 4, wherein said transmission gate comprises a plurality of transmission gates connected in parallel.

8. The differential amplifier circuit according to claim 6, wherein each of said transmission gates has a gate length and a gate width and the gate lengths and the gate widths of respective transmission gates of said plurality of transmission gates are different from the gate lengths and gate widths of other transmission gates.

9. The differential amplifier circuit according to claim 1, wherein each of said first and second inductors comprises a plurality of inductors connected in parallel.

10. The differential amplifier circuit according to claim 1, wherein said first and second transmission gates are analogically controlled.

11. The differential amplifier circuit according to claim 4, wherein said transmission gates are analogically controlled.

12. The differential amplifier circuit according to claim 1, wherein said first and second transmission gates are digitally controlled.

13. The differential amplifier circuit according to claim 4, wherein said transmission gates are digitally controlled.

14. The differential amplifier circuit according to claim 1, wherein each of said first and second transmission gates comprises a PMOS transistor connected in parallel with an NMOS transistor, or one of a PMOS transistor and an NMOS transistor.

15. The differential amplifier circuit according to claim 4, wherein each of said transmission gates comprises a PMOS transistor connected in parallel with an NMOS transistor, or one of a PMOS transistor and an NMOS transistor.

16. The differential amplifier circuit according to claim 1, wherein
said first and second transistors, and said first and second transmission gates are on a single IC chip; and said first and second inductors are inductor components of wires that connect power source terminals of said IC chip to a lead frame.

17. The differential amplifier circuit according to claim 4, wherein
said first and second transistors, and said transmission gates are on a single IC chip; and
said first and second inductors are inductor components of wires that connect power source terminals of said IC chip to a lead frame.
